(19) United States
(12) Patent Application Publication
(10) Pub. No.: US 2015/0136223 A1
(43) Pub. Date: May 21, 2015

(54) SOLAR CELL AND METHOD FOR MANUFACTURING THE SAME

(71) Applicant: SAMSUNG SDI CO., LTD., Yongin-si (KR)

(72) Inventor: Dong-Jin Kim, Yongin-si (KR)

(21) Appl. No.: 14/511,098

(22) Filed: Oct. 9, 2014

(30) Foreign Application Priority Data
Nov. 20, 2013 (KR) 10-2013-0141611

(51) Int. Cl. H01L 31/032; H01L 31/18; H01L 31/0216; H01L 31/0224

(52) U.S. Cl. CPC H01L 31/0323; H01L 31/022466; H01L 31/1876; H01L 31/02167
USPC 136/256; 438/98

(57) ABSTRACT

A solar cell according to an example embodiment includes: a substrate; a plurality of first electrodes formed on the substrate and separated by a plurality of first separation grooves; a barrier layer formed in each of the first separation grooves; a photoactive layer formed on the first electrode and the barrier layer and including a through-groove that exposes a neighboring first electrode; and a second electrode formed on the photoactive layer and electrically connected with a neighboring first electrode through the through-groove.

### CROSS-REFERENCE TO RELATED APPLICATION

This application claims priority to and the benefit of Korean Patent Application No. 10-2013-0141611, filed in the Korean Intellectual Property Office on Nov. 20, 2013, the entire content of which is incorporated herein by reference.

### BACKGROUND

1. Field

The following description relates generally to a solar cell. 2. Description of the Related Art

As a photovoltaic element that converts solar energy to electrical energy, a solar cell is gaining much interest as an unlimited and non-polluting next generation energy source.

A solar cell includes a p-type semiconductor and an n-type semiconductor, and when solar energy is absorbed at a photoactive layer, an electron-hole pair (EHP) is generated, the generated electrons and holes move to the n-type semiconductor and the p-type semiconductor respectively, and are collected by electrodes, to thereby be used (utilized) as electrical energy.

As the photoactive layer, a compound semiconductor including group elements may be used (utilized). The compound semiconductor may realize a high efficiency solar cell with a high light absorption coefficient and high optical stability.

When soda-lime glass is used (utilized) as a substrate of the solar cell including such a compound semiconductor, sodium (Na) included in the substrate may be diffused to the photoactive layer and the diffused sodium may affect efficiency of the solar cell.

However, the amount of diffused sodium (i.e., the atomic concentration of sodium atom in the photoactive layer) may vary depending on locations due to a layer structure between the substrate and the photoactive layer (to be discussed in more detail later). Here, the variation of the diffused sodium according to the locations may deteriorate efficiency of the solar cell.

The above information disclosed in this Background section is only for enhancement of understanding of the background of the described technology and therefore it may contain information that does not form the prior art that is already known in this country to a person of ordinary skill in the art.

### SUMMARY

An aspect according to one or more embodiments of the present invention is directed toward a solar cell including a copper indium gallium selenide (CIGS) semiconductor. The described technology has been made in an effort to provide a CIGS-based solar cell of which a photoactive layer has a uniform amount of sodium, and a method for manufacturing the same.

A solar cell according to an example embodiment includes: a substrate; a plurality of first electrodes on the substrate and separated by first separation grooves; a barrier layer in each of the first separation grooves; a photoactive layer on a corresponding first electrode of the first electrodes and the barrier layer, the photoactive layer including a through-groove exposing a neighboring first electrode of the first electrodes; and a second electrode on the photoactive layer and electrically connected with the neighboring first electrode through the through-groove. A thickness X of the barrier layer is calculated according to Equation 1.

Y=(−0.388)*In(X)+2.25 Equation 1

where Y is a ratio of the amount of sodium in a region (or area) of the photoactive layer overlapping with the barrier layer with respect to the amount of sodium in a region of the photoactive layer overlapping with areas other than the barrier layer.

The barrier layer may include an insulating material, and the insulating material may include at least one of SiOₓ, SiNₓ, and SiOₓN_{y}. The thickness X of the barrier layer may be 20.3 nm to 30.3 nm.

The first electrode may include molybdenum, and the second electrode may include IZO, ITO, and/or AZO.

The photoactive layer may include a CIGS-based material.

The second electrode may include a second separation groove exposing the neighboring first electrode, and the through-groove may be between a corresponding one of the first separation grooves separating the corresponding first electrode from the neighboring first electrode and the second separation groove.

According to another example embodiment, a method of manufacturing a solar cell includes: forming a plurality of first electrodes including a plurality of first separation grooves on a substrate; forming a barrier layer including an insulating material in each of the first separation grooves; forming a photoactive layer on a corresponding first electrode of the first electrodes and the barrier layer, the photoactive layer including a through-groove configured to expose a neighboring first electrode of the first electrodes; and forming a second electrode electrically connected with the neighboring first electrode through the through-groove on the photoactive layer. A thickness X of the barrier layer may be calculated according to Equation 1.

Y=(−0.388)*In (X)+2.25 Equation 1

where Y is a ratio of the amount of sodium in a region of the photoactive layer overlapping with the barrier layer with respect to the amount of sodium in a region of the photoactive layer overlapping with areas other than the barrier layer.

The forming the barrier layer may include: disposing a deposition mask configured to expose the first separation grooves on the first electrodes; depositing the insulating material to each of the first separation grooves using (utilizing) a chemical vapor deposition or sputtering method; and removing the deposition mask.

The barrier layer may include at least one of SiNₓ, SiOₓ, and SiOₓN_{y}.

According to the example embodiments, the solar cell is formed so that a content of sodium in a photoactive layer becomes uniform, thereby increasing efficiency of the solar cell.

### BRIEF DESCRIPTION OF THE DRAWINGS

FIG. 1 is a schematic top plan view of a solar cell according to an example embodiment.

FIG. 2 is a cross-sectional view of FIG. 1, taken along the line II-II.

FIG. 3 to FIG. 6 are cross-sectional views showing intermediate acts of a method for manufacturing a solar cell according to an example embodiment.

### DETAILED DESCRIPTION

The present invention will be described more fully hereinafter with reference to the accompanying drawings, in which example embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Expressions such as “at least one of,” when preceding a list of elements, modify the entire list of elements and do not modify the individual elements of the list. Further, the use of “may” when describing embodiments of the present invention refers to “one or more embodiments of the present invention.”

Hereinafter, a solar cell will be described in more detail with reference to the accompanying drawings.

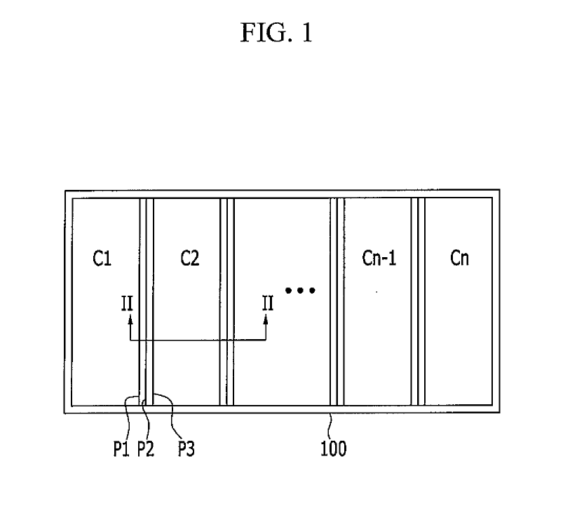

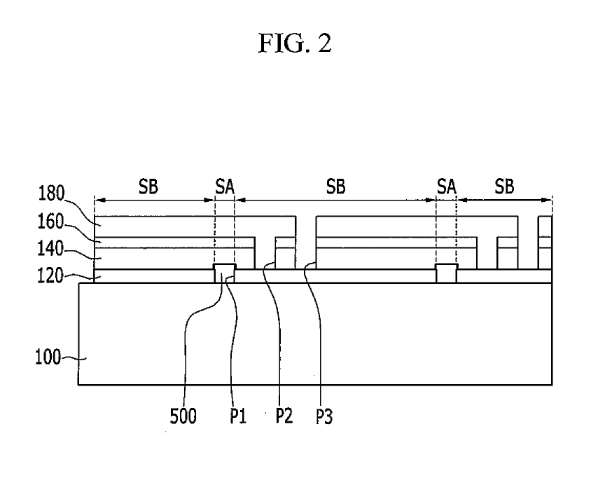

FIG. 1 is a schematic top plan view of a solar cell according to an example embodiment, and FIG. 2 is a cross-sectional view of FIG. 1, taken along the line II-II.

As shown in FIG. 1 and FIG. 2, a solar cell according to an example embodiment includes a plurality of cells C1 to Cn formed on a substrate 100. Each cell includes a first electrode 120, a photoactive layer 140 formed on the first electrode 120, a buffer layer 160 formed on the photoactive layer 140, and a second electrode 180 formed on the buffer layer 160, and every neighboring cells (e.g., C1 and C2) are electrically connected with each other.

Referring to FIG. 2, a layer structure of the solar cell of FIG. 1 will be described in further detail.

As shown in FIG. 2, a plurality of first electrodes 120 are formed on the substrate 100. The first electrodes 120 are separated from each other by first separation grooves P1 that are formed to have a constant gap (i.e., a gap with a constant width). Here, the width of the first separation groove P1 may be 20 μm to 100 μm.

The substrate 100 may be a transparent and insulating glass substrate such as soda-lime glass.

The first electrode 120 may be made of a metal having a suitable (e.g., an excellent) heat resistance characteristic, a suitable (e.g., an excellent) electric contact characteristic with respect to a material that forms the photoactive layer 140, a suitable (e.g., an excellent) electrical conductivity, and a suitable (e.g., an excellent) interface adherence with the substrate 100. For example, the first electrode 120 may be made of molybdenum (Mo).

A barrier layer 500 is formed in the first separation groove P1. The barrier layer 500 may be made of an insulating material that insulates between every neighboring first electrodes 130 while filling in the first separation groove P1, and for example, may include at least one of SiOₓ, SiNₓ, and SiOₓN_{y}.

A photoactive layer 140 and a buffer layer 160 are formed on each of the first electrodes 120.

The photoactive layer 140 is a p-type CIS-based semiconductor, and may include selenium (Se) and/or sulfur (S). For example, the photoactive layer 140 may include Cu (In₁₋ₓ,Gaₓ)(Se₁₋ₓ,Sₓ) as a group I-III-VI-based semiconductor compound, and may be a compound semiconductor having a composition of 0≦×≦1. The photoactive layer 140 may have a single phase of which the composition in the compound semiconductor is substantially uniform throughout the photoactive layer. For example, the photoactive layer 140 may include CuInSe₂, CuInS₂, Cu(In,Ga)Se₂, (Ag,Cu) (In,Ga)Se₂, (Ag,Cu) (In,Ga) (Se,S)₂, Cu(In,Ga) (Se,S)₂, and/or Cu(In,Ga)S₂.

The photoactive layer 140 may further include sodium (Na), which is diffused from the substrate 100.

The buffer layer 160 is made of an n-type semiconductor material having high light transmittance, and reduces an energy gap difference between the photoactive layer 140 and the second electrode 180. The buffer layer 160 is made of an n-type semiconductor material having high light transmittance, and for example, may be made of cadmium sulfide (CdS), zinc sulfide (ZnS) and/or indium sulfide (InS).

The buffer layer 160 and the photoactive layer 140 include a through-groove P2 that exposes the first electrodes 120. Here, the through-groove P2 exposes the first electrodes 120 of neighboring cells (e.g., the buffer layer 160 and the photoactive layer 140 include a through-groove P2 which exposes a first electrode 120 directly under the through-groove P2). In one embodiment, the buffer layer 160 and the photoactive layer 140 include a plurality of through-grooves P2, each exposing a corresponding one of the plurality of first electrodes 120 directly under that through-groove P2. The through-groove P2 may have a width of 20 μm to 100 μm.

A second electrode 180 is formed on the buffer layer 160.

The second electrode 180 may be made of a material having high light transmittance and suitable (e.g., excellent) electrical conductivity, and for example, may be formed in a single layer or a multilayer of iridium tin oxide (ITO), indium zinc oxide (IZO), and/or zinc oxide (ZnO). The light transmittance may be over about 80%. Here, the ZnO layer may have a low resistance value by being doped with aluminum (Al) and/or boron (B).

When the second electrode 180 is formed in a multilayer, an ITO layer (having an excellent electro-optical characteristic) may be layered on a ZnO layer, or an n-type ZnO layer (having a low resistance value by being doped with a conductive impurity) may be layered on an i-type (intrinsic) ZnO layer (that is not doped with a conductive impurity).

The second electrode 180 is an n-type semiconductor, and forms a pn junction with the photoactive layer 140, which is a p-type semiconductor.

The second electrode 180 includes a second separation groove P3 that exposes the first electrode 120. Here, the second separation groove P3 exposes the first electrodes 120 of a neighboring cell (e.g., the second electrode 180 includes a second separation groove P3 which exposes a first electrode 120 directly under the second separation groove P3). In one embodiment, the second electrode 180 includes a plurality of second separation grooves P3, each exposes one of the plurality of first electrodes 120 directly under that second separation groove P3. The second separation groove P3 may have a width of 20 μm to 100 μm.

According to the example embodiment, sodium content of the photoactive layer may be made uniform throughout the substrate by forming a barrier layer in the first separation groove.

When sodium is diffused to the photoactive layer 140, the amount of sodium passing through the first separation groove P1 and the amount of sodium passing through the first electrode 120 become similar to each other due to the barrier layer 500, thereby maintaining the amount of sodium diffused throughout the substrate 100 to be uniform. Here, the thickness X of the barrier layer 500 may be acquired (determined) according to Equation 1.

Y=(−0.388)*In(X)+2.25 Equation 1

where Y is a ratio of the amount of sodium in an area SA of the photoactive layer that overlaps with the barrier layer with respect to the amount of sodium in an area SB of the photoactive layer overlapping with areas other than the barrier layer. Hereinafter, a method for manufacturing a solar cell according to an example embodiment will be described with reference to FIG. 2 and FIG. 3 to FIG. 6.

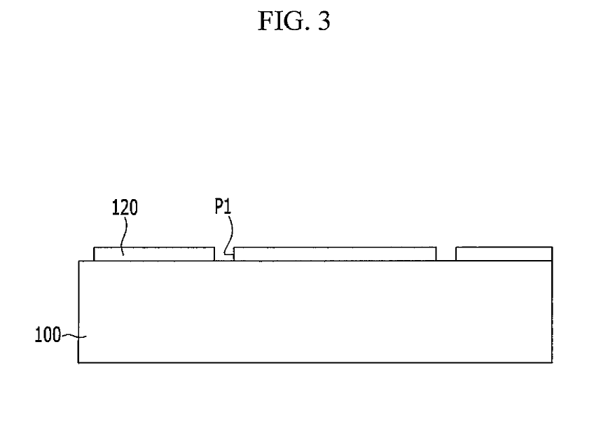

FIG. 3 to FIG. 6 are cross-sectional views of intermediate acts in manufacturing of a solar cell according to an example embodiment.

As shown in FIG. 3, a metal layer (such as one made of molybdenum) is formed on a substrate 100 using (utilizing) a sputtering method.

Then, a plurality of first electrodes 120 are formed by forming separation grooves P1 using (utilizing) a laser or a dicing saw.

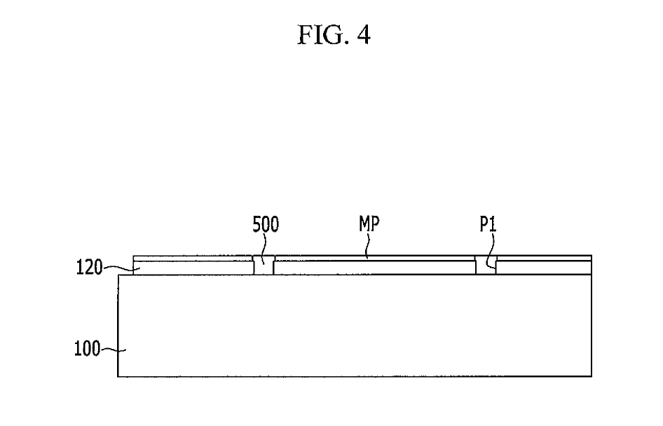

As shown in FIG. 4, barrier layers 500 are formed by filling in the first separation grooves P1 with an insulating material.

A deposition mask MP that exposes the first separation grooves P1 is disposed on the first electrode 120 and then the insulation material is deposited to the first separation grooves P1 using (utilizing) a chemical vapor deposition (CVD) method or a sputtering method such that the barrier layer 500 is formed.

Here, the thickness of the barrier layer 500 may be determined according to Equation 1 as previously described.

For example, referring to FIG. 2, when the amount of sodium is uniform through the entire area of the photoactive layer, the amount of sodium of an area SA and the amount of sodium of an area SB are equivalent to each other. Therefore, the ratio Y of the amount of sodium of the area SA with respect to the amount of sodium of the area SB becomes 1. In one embodiment, the amount of sodium of the area SB may be 0.5 at %, and the barrier layer 500 may be made of at least one of SiOₓ, SiNₓ, and SiOₓN_{y}.

Since Y becomes 1, the thickness X of the barrier layer 500 becomes 25.3 nm according to Equation 1, and therefore the barrier layer 500 may have a thickness of 25.3 nm. Here, a process error may occur depending on location of the barrier layer 500 in the substrate 100, and the thickness of the barrier layer 500 may be 20.3 nm to 30.3 nm.

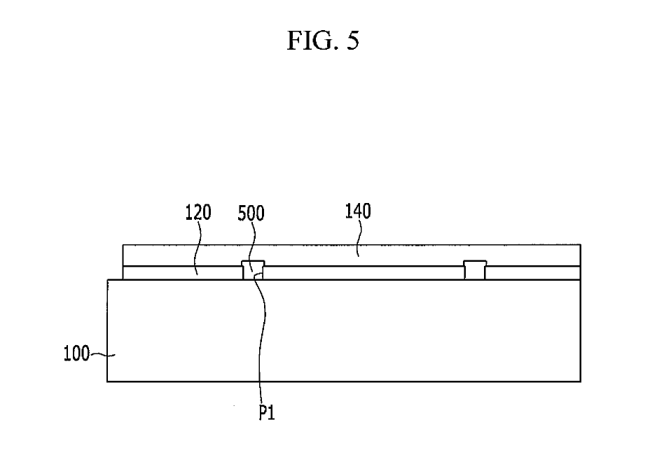

Next, as shown in FIG. 5, a photoactive layer 140 is formed on the first electrode 120 after removing the deposition mask. The photoactive layer 140 may be formed using (utilizing) a selenization process or an evaporation method after a sputtering process.

For example, the sputtering process and the selenization process may sequentially form a first thin film (including a compound of group I and group III elements) and a second thin film (including a group III element). Here, the first thin film and the second thin film are precursor thin films for forming the photoactive layer. In addition, the second thin film may be formed first and then the first thin film may be formed, or the first thin film and the second thin film may be formed alternately in a multiple-layered structure as necessary.

The group I element may be, for example, copper (Cu), silver (Ag), gold (Au) or a combination thereof, and the group III element may be, for example, indium (In), gallium (Ga), or a combination thereof.

The group III element of the first thin film and the group III element of the second thin film may be different from each other. For example, the group III element of the first thin film may be gallium and the group III element of the second thin film may be indium. Here, the group I element may be copper.

Then, a heat treatment is performed under an atmosphere of a gas containing group VI elements (such as selenium (Se) or sulfur (S)) so as to complete the formation of the photoactive layer 140. Here, the heat treatment may be conducted at about 400° C. to about 600° C. for about 30 minutes to about 120 minutes. When the heat treatment is performed, an upper surface of the first electrode (contacting the photoactive layer 140) may react with Se such that a MoSe₂ layer may be formed. The MoSe₂ layer forms an ohmic junction between the first electrode and the photoactive layer to thereby reduce a contact resistance.

Alternatively, the evaporation method may form the photoactive layer on the substrate using (utilizing) a plurality of evaporation sources.

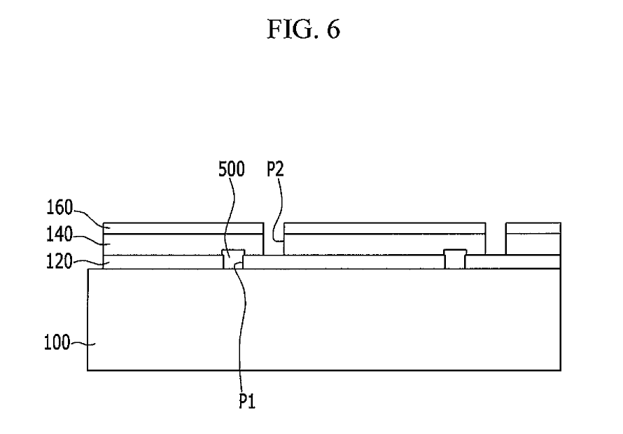

As shown in FIG. 6, a buffer layer 160 is formed on the photoactive layer 140. Then, a through-groove P2 is formed in the buffer layer 160 and the photoactive layer 140 using (utilizing) scribing.

As shown in FIG. 2, a second electrode 180 is formed on the buffer layer 160, and then the second separation groove P3 is formed using (utilizing) scribing so that the substrate 100 is separated into the respective cells.

The second electrode 180 may be made of ZnO by depositing a ZnO target with a direct current (DC) or a radio frequency (RF) sputtering method, or by using (utilizing) a reactive sputtering method using (utilizing) a Zn target, or an organic metal chemical vapor deposition method.

While this disclosure has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims, and equivalents thereof.

Description of symbols

| | |
|---|---|
| 100: substrate | 120: first electrode |
| 140: photoactive layer | 160: buffer layer |
| 180: second electrode | 500: barrier layer |

What is claimed is:

1. A solar cell comprising:
a substrate;
a plurality of first electrodes on the substrate and separated by first separation grooves;
a barrier layer in each of the first separation grooves;
a photoactive layer on a corresponding first electrode of the first electrodes and the barrier layer, the photoactive layer including a through-groove exposing a neighboring first electrode of the first electrodes; and
a second electrode on the photoactive layer and electrically connected with the neighboring first electrode through the through-groove,
wherein a thickness X of the barrier layer is calculated according to Equation 1:
Y=(−0.388)*In(X)+2.25 Equation 1
where Y is a ratio of an amount of sodium in a region of the photoactive layer overlapping with the barrier layer with respect to an amount of sodium in a region of the photoactive layer overlapping with areas other than the barrier layer.

2. The solar cell of claim 1, wherein the barrier layer comprises an insulating material.

3. The solar cell of claim 2, wherein the insulating material comprises at least one of SiOₓ, SiNₓ, and SiOₓN_{y}.

4. The solar cell of claim 1, wherein the first electrode comprises molybdenum, and the second electrode comprises IZO, ITO, and/or AZO.

5. The solar cell of claim 1, wherein the photoactive layer comprises a CIGS-based material.

6. The solar cell of claim 1, wherein the second electrode comprises a second separation groove exposing the neighboring first electrode, and
the through-groove is between a corresponding one of the first separation grooves separating the corresponding first electrode from the neighboring first electrode and the second separation groove.

7. The solar cell of claim 1, wherein the thickness X of the barrier layer is 20.3 nm to 30.3 nm.

8. A method for manufacturing a solar cell, the method comprising:
forming a plurality of first electrodes including a plurality of first separation grooves on a substrate;
forming a barrier layer comprising an insulating material in each of the first separation grooves;
forming a photoactive layer on a corresponding first electrode of the first electrodes and the barrier layer, the photoactive layer including a through-groove configured to expose a neighboring first electrode of the first electrodes; and
forming a second electrode electrically connected with the neighboring first electrode through the through-groove on the photoactive layer,
wherein a thickness of the barrier layer is calculated according to Equation 1:
Y=(−0.388)*In(X)+2.25 Equation 1
where Y is a ratio of an amount of sodium in a region of the photoactive layer overlapping with the barrier layer with respect to an amount of sodium in a region of the photoactive layer overlapping with areas other than the barrier layer.

9. The method for manufacturing the solar cell of claim 8, wherein the forming the barrier layer comprises:
disposing a deposition mask configured to expose the first separation grooves on the first electrodes;
depositing the insulating material to each of the first separation grooves utilizing a chemical vapor deposition or a sputtering method; and
removing the deposition mask.

10. The method for manufacturing the solar cell of claim 8, wherein the barrier layer comprises at least one of SiNₓ, SiOₓ, and SiOₓN_{y}.
